(19) United States
(12) Patent Application Publication
(10) Pub. No.: US 2024/0079421 A1
(43) Pub. Date: Mar. 7, 2024

(54) IMAGE SENSOR

(71) Applicants: COMMISSARIAT A L'ENERGIE ATOMIQUE ET AUX ENERGIES ALTERNATIVES, Paris (FR); STMicroelectronics (Crolles 2) SAS, Crolles (FR)

(72) Inventors: Axel CROCHERIE, Grenoble (FR); Alain OSTROVSKY, Grenoble (FR); Jerome VAILLANT, Grenoble (FR); Francois DENEUVILLE, Grenoble (FR)

(73) Assignees: COMMISSARIAT A L'ENERGIE ATOMIQUE ET AUX ENERGIES ALTERNATIVES, Paris (FR); STMicroelectronics (Crolles 2) SAS, Crolles (FR)

(21) Appl. No.: 18/186,115

(22) Filed: Mar. 17, 2023

(30) Foreign Application Priority Data
Sep. 6, 2022 (FR) 2208887

(51) Int. Cl. H01L 27/146

(52) U.S. Cl. CPC H01L 27/14607; H01L 27/14603; H01L 27/14643

(57) ABSTRACT

The present description concerns an image sensor formed inside and on top of a semiconductor substrate, the sensor comprising a plurality of pixels, each comprising a photodetector formed in the substrate, the sensor comprising at least first and second bidimensional metasurfaces stacked, in this order, in front of said plurality of pixels, each metasurface being formed of a bidimensional array of pads, the first metasurface having a first optical function and the second metasurface having a second optical function different from the first optical function.

### BACKGROUND

### Technical Field

The present disclosure is directed to image sensors.

### Description of the Related Art

An image sensor conventionally comprises a plurality of pixels, for example, arranged in an array of rows and columns, integrated inside and on top of a semiconductor substrate. Each pixel conventionally comprises a photodetector, for example, a photodiode, formed in the semiconductor substrate.

For certain applications, optical elements, for example, focusing elements, wavelength filtering elements, or also polarization filtering elements, may be placed in front of the photodetectors.

It would be desirable to at least partly improve certain aspects of known image sensors.

### BRIEF SUMMARY

For this purpose, an embodiment provides an image sensor formed inside and on top of a semiconductor substrate, the sensor comprising a plurality of pixels, each comprising a photodetector formed in the substrate, the sensor comprising at least first and second bidimensional metasurfaces stacked, in this order, in front of said plurality of pixels, each metasurface being formed of a bidimensional array of pads, the first metasurface having a first optical function and the second metasurface having a second optical function different from the first optical function.

According to an embodiment, the first and second metasurfaces are at a distance from the semiconductor substrate shorter than 500 μm, for example, shorter than 100 μm.

According to an embodiment, the first metasurface is at a distance from the semiconductor substrate in the range from 1 to 50 μm, and the second metasurface is at a distance from the first metasurface in the range from 1 to 50 μm.

According to an embodiment, the pads of the first metasurface and the pads of the second metasurface are made of amorphous silicon.

According to an embodiment, the pads of the first metasurface and the pads of the second metasurface are laterally surrounded with silicon oxide.

According to an embodiment, the pads of the first and second metasurfaces have sub-wavelength lateral dimensions.

According to an embodiment, the first optical function is a function of routing of the incident light according to its polarization state, and the second optical function is a function of focusing of light towards the photodetectors of the underlying pixels.

According to an embodiment, the sensor includes a layer of color filters between the first metasurface and the substrate.

According to an embodiment, the sensor includes a layer of color filters above the second metasurface.

According to an embodiment, the sensor includes, above the second metasurface, a third metasurface adapted to implementing an optical function of routing of the incident light according to its wavelength.

According to an embodiment, the first optical function is a function of routing of the incident light according to its polarization state, and the second optical function is a function of routing and focusing of light towards the photodetectors of the underlying pixels, according to its wavelength.

According to an embodiment, in top view, the pads of the first metasurface and/or the pads of the second metasurface have asymmetrical shapes, for example, rectangular or elliptic.

### BRIEF DESCRIPTION OF THE SEVERAL VIEWS OF THE DRAWINGS

The foregoing features and advantages, as well as others, will be described in detail in the rest of the disclosure of specific embodiments given by way of illustration and not limitation with reference to the accompanying drawings, in which:

FIG. 1A and FIG. 1B are respectively an exploded perspective view and a cross-section view of an example of an image sensor according to an embodiment;

FIG. 2A and FIG. 2B respectively are an exploded perspective view and a cross-section view of another example of an image sensor according to an embodiment;

FIG. 3A and FIG. 3B respectively are an exploded perspective view and a cross-section view of another example of an image sensor according to an embodiment;

FIG. 4 is a cross-section view of another example of an image sensor according to an embodiment;

FIG. 5 is a cross-section view of another example of an image sensor according to an embodiment; and

FIG. 6A, FIG. 6B, FIG. 6C, FIG. 6D, FIG. 6E, and FIG. 6F are cross-section views schematically and partially illustrating steps of an example of a method of manufacturing an image sensor according to an embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the photodetectors and the electronic circuits for controlling the described image sensors have not been detailed, the described embodiments being compatible with usual embodiments of these elements. Further, the possible applications of the described image sensors have not been detailed.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, when reference is made to absolute positional qualifiers, such as the terms “front,” “back,” “top,” “bottom,” “left,” “right,” etc., or to relative positional qualifiers, such as the terms “above,” “below,” “upper,” “lower,” etc., or to qualifiers of orientation, such as “horizontal,” “vertical,” etc., reference is made, unless specified otherwise, to the orientation of the figures.

Unless specified otherwise, the expressions “around,” “approximately,” “substantially” and “in the order of” signify within 10%, and preferably within 5%.

According to an aspect of the described embodiments, an image sensor formed inside and on top of a semiconductor substrate, for example, made of silicon, for example, single-crystal silicon, is provided. The sensor comprises a plurality of pixels, for example arranged in an array of rows and columns, each pixel comprising a photodetector formed in the substrate.

The sensor comprises at least first and second stacked bidimensional (2D) metasurfaces in front of said plurality of pixels. Each metasurface is formed of a bidimensional array of pads of a first material laterally surrounded with a second material. The pads of each metasurface have sub-wavelength lateral dimensions, that is, the largest lateral dimension of each pad is smaller than the main wavelength intended to be measured by the underlying pixel, that is, the wavelength for which the quantum efficiency of the pixel is maximum. For example, for pixels intended to measure visible or near-infrared radiations, for example, radiations having a wavelength smaller than 1 μm, the largest dimension of each pad is in the range from 10 to 500 nm, for example from 30 to 300 nm.

The first and second metasurfaces are adapted to implementing different optical functions. For example, the first metasurface is adapted to implementing a first optical routing, filtering, or focusing function, and the second metasurface is adapted to implementing a second optical routing, filtering, or focusing function, different from the first function.

In practice, each metasurface comprises, in front of each pixel, a plurality of pads of varied lateral dimensions. The sizing and the arrangement of the pads are defined according to the optical function which is desired to be performed. For example, to achieve a polarization routing or routing or polarized light focusing function, pads having, in top view, asymmetrical shapes, for example, rectangular or elliptic, may be provided. The pattern of each metasurface can be defined by means of electromagnetic simulation tools, for example by using inverse design methods, for example of the type described in the article entitled “Phase-to-pattern inverse design paradigm for fast realization of functional metasurfaces via transfer learning” by Zhu, R., Qiu, T., Wang, J. et al. Nat Commun 12, 2974 (2021), or in the article entitled “Matrix Fourier optics enables a compact full-Stokes polarization camera” by Rubin et al. (SCIENCE-Volume 365-Issue 6448-5 Jul. 2019).

The pads of each metasurface preferably all have the same height, for example smaller than the main wavelength intended to be measured by each pixel, for example, in the range from 50 to 500 nm for radiations of wavelength smaller than 1 μm. The provision of pads of constant height across the entire surface of the sensor advantageously enables to simplify the manufacturing of the metasurfaces.

It should be noted that it has already been provided to arrange a metasurface in front of an image, in far field, that is at relatively large distance from the surface of illumination of the semiconductor substrate of the sensor, to implement an optical processing function, for example, of routing or of focusing, of the light rays transmitted to the sensor. The metasurface is then manufactured separately from the sensor, on a specific substrate, distinct from the semiconductor substrate of the sensor. The metasurface is then integrated to an optical system arranged in front of the sensor during an assembly phase. In this case, the metasurface manufacturing constraints, and in particular, the constraints relative to the sizing and to the positioning of the pads of the metasurface, are decorrelated from the image sensor manufacturing constraints.

According to an aspect of the described embodiments, it is here provided to integrate at least two stacked metasurfaces to the image sensor, at the scale of the sensor pixels. In other words, in the described embodiments, the metasurfaces are formed on the semiconductor substrate of the sensor, at a relatively short distance from the substrate illumination surface, for example, at a distance shorter 100 μm, preferably shorter than 100 μm, preferably shorter than 10 μm, from the substrate illumination surface. As an example, the first metasurface is arranged at a distance in the range from 1 to 10 μm, for example in the order of 4 μm, from the substrate illumination surface, and the second metasurface is arranged on the side of the first metasurface opposite to the substrate, for example at distance in the range from 1 to 10 μm, for example in the order 4 μm, from the first metasurface.

The fact of breaking down the desired general optical function into a plurality of distinct elementary optical functions respectively implemented by a plurality of stacked metasurfaces enables to simplify the design and the manufacturing of the metasurfaces with a respect to a single metasurface implementing a complex optical function. This allows in particular an integration of the metasurfaces directly on the semiconductor substrate of the sensor, at the scale of the sensor pixels. In particular, this enables to make the integration of the metasurfaces compatible with the constraints of methods of microelectronics conventionally used for the manufacturing of an image sensor.

The quality of the images acquired by means of the sensor is thereby improved and/or the assembly of the sensor in a final device, for example, is thereby simplified. In particular, this for example enables to decrease the complexity of possible optical far field optical systems arranged in front of sensors.

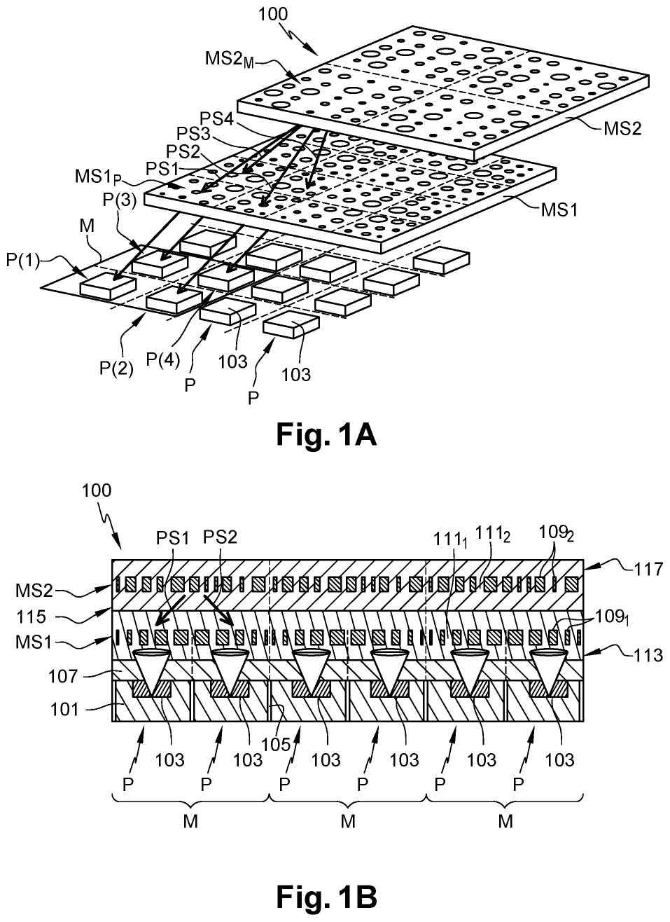

FIG. 1A and FIG. 1B are respectively an exploded perspective view and a cross-section view schematically and partially illustrating an example of an image sensor 100 according to an embodiment.

Sensor 100 comprises a semiconductor substrate 101 (FIG. 1B) having a plurality of pixels P formed inside and on top of it. Substrate 101 is for example made of silicon, for example, of single-crystal silicon. The described embodiments are however not limited to this specific example. As a variant, sensor 100 may be formed based on a substrate made of a III-V-type semiconductor material, on a quantum film, or on any known photosensitive material, organic or inorganic.

Each pixel comprises a photodetector 103, for example a photodiode, formed in substrate 101.

In the shown example, insulating trenches or walls 105, extending vertically in substrate 101, laterally separate from one another, electrically and/or optically, the photodetectors 103 of the pixels.

In this example, sensor 100 comprises a layer 107, for example, an insulating passivation layer, arranged on top of and in contact with the upper surface of the substrate.

In this example, sensor 100 is a back-side illumination sensor or BSI sensor, that is, the light rays originating from the scene to be imaged reach substrate 101 on its back side, that is, its surface opposite to an interconnection stack (not visible in the drawings) comprising elements of interconnection of the sensor pixels, that is, its upper surface in the orientation of the drawings. The described embodiments however also apply to front side illumination sensors or FSI sensors, that is, sensors where the substrate is intended to be illuminated on its surface in contact with the interconnection stack.

For simplification, only the photodetectors 103 of pixels P have been shown in FIG. 1A. In this example, pixels P are arranged in an array of rows and columns. The pixels P of the sensor are for example all identical, to within manufacturing dispersions, or similar.

The sensor 100 of FIG. 1A comprises two metasurfaces MS1 and MS2 stacked, in this order, in front of the array of pixels P.

In this example, metasurface MS2, the most distant from substrate 101, has a polarization routing function, that is, a polarization sorting function, and metasurface MS1, located between metasurface MS2 and substrate 101, has a function of light focusing towards the photodetectors 103 of the sensor.

In this example, sensor 100 is a polarimetric sensor, adapted to measuring, by means of distinct pixels P, intensities of light radiations received according to different polarizations.

More particularly, in this example, the pixels P of the sensor are distributed into macropixels M, each formed by a sub-array of 2×2 adjacent pixels P. The sensor macropixels M are for example all identical, to within manufacturing dispersions, or similar.

In this example, the four pixels P of a same macropixel M are intended to measure light radiation intensities received respectively according to four different polarization orientations, for example, linear polarizations according to respectively four directions respectively forming 0°, 90°, +45°, and −45° angles with respect to a reference direction. The polarization states intended to be respectively measured by the four pixels P of each macropixel are here called PS1, PS2, PS3, and PS4.

The portion MS2_{M} of metasurface MS2 located vertically in line with each macropixel M exhibits a pattern adapted to implementing a function of routing of the light rays received according to the four polarization states PS1, PS2, PS3, and PS4 to respectively the four pixels P(1), P(2), P(3), and P(4) of the macropixel. By routing, also called sorting, function, there is here meant that the entire light flux received by the portion MS2_{M} of metasurface MS2, having a surface area substantially equal to the total surface area of macropixel M, is sorted according to respectively the four polarization states PS1, PS2, PS3, and PS4. The components of the incident flux polarized according to states P51, PS2, PS3, and PS4 are deviated towards respectively the pixels P(1), P(2), P(3), and P(4) of the macropixel. As an example, the received light flux is sorted according to two orthogonal polarization states, respectively PS1 and PS2 or PS3 and PS4. A photon arriving above P(1)/P(2) will then be sorted into PS1 or PS2, and a photon arriving above P(3)/P(4) will be sorted into PS3 or PS4.

As compared with a polarimetric sensor based on polarizing filters, this advantageously enables to improve the quantum efficiency of the sensor since the entire flux collected in front of each macropixel M is transmitted to the four pixels P(1), P(2), P(3), and P(4) of the macropixel.

The pattern of the portion MS2_{M} of metasurface MS2 may be identically repeated (to within manufacturing dispersions) in front of all the sensor macropixels M. As a variant, the pattern of portion MS2_{M} may vary from one macropixel M to the other, according to the position of the macropixel on the sensor, to take into account, in particular, the main direction of incidence of the rays arriving on metasurface MS2 from the scene to be imaged.

The portion MS1_{P} of metasurface MS1 located vertically in line with each pixel P exhibits a pattern adapted to implementing a function of focusing of the received light rays towards the photodetector 103 of the underlying pixel. In other words, the portion MS1_{P} of metasurface MS1 located vertically in line with each pixel P behaves as a microlens focusing towards the photodetector 103 of the pixel the rays transmitted by the portion MS2_{M} of metasurface MS2, covering the macropixel M to which the pixel belongs.

The pattern of the portion MS1_{P} of metasurface MS1 may be repeated identically (to within manufacturing dispersions) in front of all the pixels P of the sensor. As a variant, the pattern of portion MS2_{M} may vary from one pixel P to the other, according to the position of the macropixel on the sensor, to take into account, for example, the main direction of incidence of the rays arriving on metasurface MS1 from metasurface MS2, and/or the polarization state which is desired to be measured by means of pixel P.

Each of metasurfaces MS1, MS2 is formed of a bidimensional array of pads 109₁, respectively 109₂ of a first material, laterally surrounded with a filling material 111₁, respectively 111₂. Pads 109₁ and/or 109₂ are for example made of a material opaque to the radiation to be measured, for example, a metal. As a variant, pads 109₁ and/or 109₂ are made of a material transparent or partially transparent to the radiation to be measured, for example amorphous silicon or silicon nitride. Filling materials 111₁ and/or 111₂ are for example transparent materials for example, transparent materials having a refraction index smaller than that of the material of pads 109₁, respectively 109₂. Filling materials 111₁ and/or 111₂ are for example silicon oxide. As a variant, filling materials 111₁ and/or 111₂ are gaseous, for example, air, or vacuum. The pads 109₁ and 109₂ of metasurfaces MS1 and MS2 may be made of the same material, or of different materials. Similarly, the filling materials 111₁ and 111₂ of metasurfaces MS1 and MS2 may be identical or different.

In this example, the pads 109₁ of metasurface MS1 all have the same height, and the pads 109₂ of metasurface MS2 all have the same height, equal to the height of pads 109₁ or different from the height of pads 109₁.

In the example of FIG. 1A, lower metasurface MS1 is separated from the upper surface of layer 107 by a transparent layer 113, for example made of the same material as the filling material of metasurface MS1. Layer 113 has an optical spacer function. The thickness of layer 113 is selected according to the optical function performed by metasurface MS1 and/or by metasurface MS2, to obtain the desired effect of focusing of the light rays into or onto the photodetectors 103 of the pixels. As an example, the thickness of layer 113 is smaller than 100 μm, preferably smaller than 10 μm, preferably in the range from 1 to 10 μm, for example, in the order of 4 μm. As an example, the pads 109₁ of metasurface MS1 are in contact, by their lower surface, with the upper surface of layer 113. Layer 113 is for example in contact, by its lower surface, with the upper surface of layer 107.

In the example of FIG. 1A, lower metasurface MS1 is separated from upper metasurface MS2 by a transparent layer 115, for example, made of the same material as the filling material of metasurface MS1 or of the same material as the filling material of metasurface MS2. Layer 115 has an optical spacer function. The thickness of layer 115 is selected according to the optical function performed by metasurface MS1 and/or by metasurface MS2, to obtain the desired effect of routing of the light rays, according to their polarization state, into or onto the photodetectors 103 of the pixels. As an example, the thickness of layer 115 is smaller than 100 μm, preferably smaller than 10 μm, preferably in the range from 1 to 10 μm, for example, in the order of 4 μm. As an example, the pads 109₁ of metasurface MS1 are in contact, by their upper surface, with the lower surface of layer 115. The pads 109₂ of metasurface MS2 are for example in contact, by their lower surface, with the upper surface of layer 115.

In the shown example, the sensor comprises a transparent layer 117, for example made of the same material as the filling material of metasurface MS2, covering the upper surface of metasurface MS2. Layer 117 is for example in contact, by its lower surface, with the upper surface of the pads 109₂ of metasurface MS2. Layer 117 for example has a function of protection of metasurface MS2.

The sensor 100 of the example of FIGS. 1A and 1B is a monochromatic sensor, that is, the photodetectors 103 of all the pixels P of sensor 100 are configured to measure light rays in a same wavelength range.

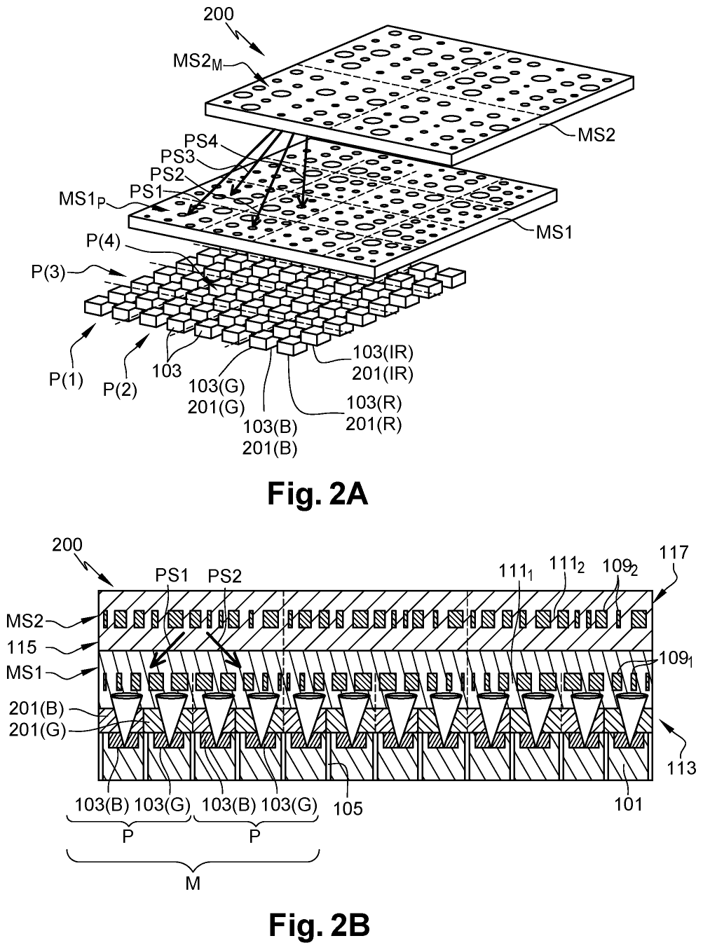

FIG. 2A and FIG. 2B are respectively an exploded perspective view and a cross-section view schematically and partially illustrating an example of an image sensor 200 according to an embodiment.

The sensor 200 of FIGS. 2A and 2B has elements common with the sensor 100 of FIGS. 1A and 1B. These elements will not be detailed again, and only the differences with respect to the sensor 100 of FIGS. 1A and 1B will be highlighted hereafter.

Sensor 200 differs from sensor 100 mainly in that, while sensor 100 is a monochromatic sensor, the sensor 200 of FIGS. 2A and 2B is a multispectral sensor, that is, adapted to measuring radiations in different wavelength ranges.

For this purpose, in sensor 200, each pixel P comprises a plurality of photodetectors 103 arranged to respectively measure light rays in different wavelength ranges. As in the example of FIGS. 1A and 1B, photodetectors 103 are laterally insulated from one another by insulating trenches or walls 105.

More particularly, in the shown example, each pixel P of sensor 200 comprises four adjacent photodetectors 103(R), 103(G), 103(B), 103(IR), arranged to respectively measure mainly red, green, blue, and infrared light radiations. For this purpose, each photodetector 103 is topped with a color filter 201 adapted to essentially letting through the light of the wavelength range to be measured. For example, in each pixel P, photodetectors 103(R), 103(G), 103(B), 103(IR) are respectively topped with filters 201(R), 201(G), 201(B), 201(IR), adapted to respectively letting through mainly red light, mainly green light, mainly blue light, and mainly infrared light. Those skilled in the art will of course be capable of adapting the embodiment of FIGS. 2A and 2B to other spectral decompositions of the measured light.

Color filters 201 for example comprise filters made of colored resins and/or interference filters.

As an example, color filters 201 form together a color filtering layer coating the upper surface of substrate 101.

Transparent layer 113 is for example in contact, by its lower surface, with the upper surface of filtering layer 201.

In the example illustrated in FIGS. 2A and 2B, the layer 107 of the example of FIGS. 1A and 1B has not been shown. As an example, the sensor 200 of FIGS. 2A and 2B is a back-side illumination sensor. In this case, an interconnection stack may be arranged on the side of the surface of substrate 101 opposite to the sensor illumination surface, that is, on the side of the lower surface of substrate 101 in the orientation of FIG. 2B. As a variant, sensor 200 is a front-side illumination sensor. In this case, an interconnection stack may be arranged between the upper surface of substrate 101 and the lower surface of filtering layer 201.

In this example, the portion MS1_{P} of metasurface MS1 located vertically in line with each pixel P, exhibits a pattern adapted to implementing a function of focusing of the received light rays towards the four photodetectors 103(R), 103(G), 103(B), 103(IR) of the underlying pixel. In other words, the portion MS1_{P} of metasurface MS1 located vertically in line with each pixel P behaves as an array of four microlenses focusing towards the photodetectors 103(R), 103(G), 103(B), 103(IR) of the pixel the rays transmitted by the portion MS2_{M} of metasurface MS2, covering the macropixel M to which the pixel belongs.

The pattern of the portion MS1_{P} of metasurface MS1 may be repeated identically (to within manufacturing dispersions) in front of all the pixels P of the sensor. As a variant, the pattern of portion MS1_{P} may vary from one pixel P to the other, according to the position of the macropixel on the sensor, to take into account, in particular, the main direction of incidence and/or the polarization state of the rays arriving on metasurface MS1 from metasurface MS2

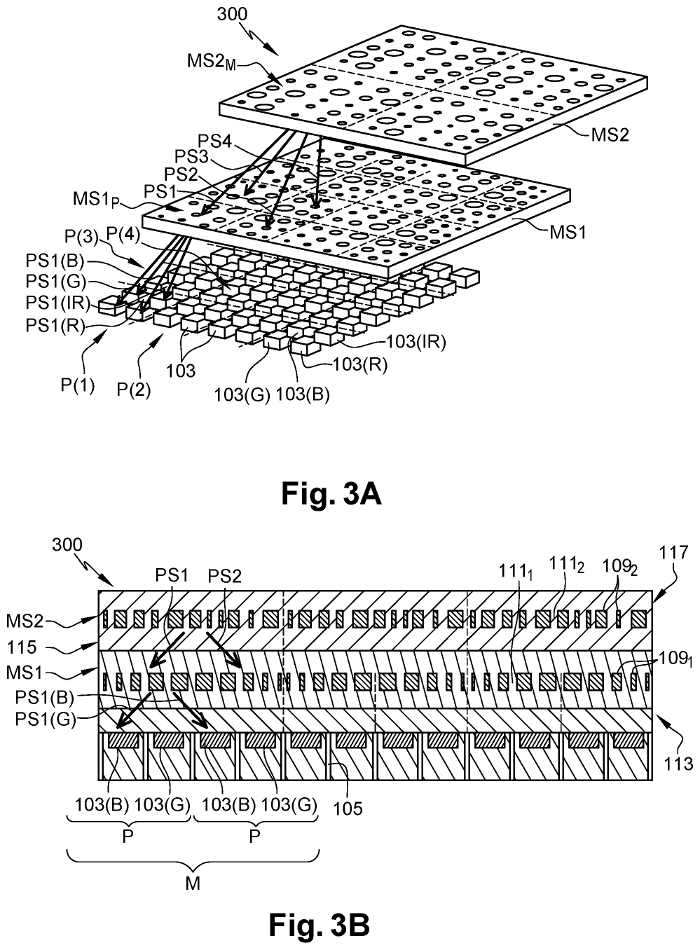

FIG. 3A and FIG. 3B are respectively an exploded perspective view and a cross-section view schematically and partially illustrating an example of an image sensor 300 according to an embodiment.

The sensor 300 of FIGS. 3A and 3B has elements common with the sensor 200 of FIGS. 2A and 2B. These elements will not be detailed again, and only the differences with respect to the sensor 200 of FIGS. 2A and 2B will be highlighted hereafter.

In the same way as for the sensor 200 of FIGS. 2A and 2B, the sensor 300 of FIGS. 3A and 3B is a multispectral sensor, that is, adapted to measuring radiations in different wavelength ranges.

However, conversely to sensor 200, the sensor 300 of FIGS. 3A and 3B comprises no spectral filters 201.

Instead, in the example of FIGS. 3A and 3B, metasurface MS1 has a function of routing and focusing of the incident light, according to its wavelength, towards respectively the different photodetectors 103 of the underlying pixels.

More particularly, in the example illustrated in the drawings, the portion MS1_{P} of metasurface MS1 located vertically in line with each pixel P, exhibits a pattern adapted to implementing a function of routing and focusing:
of red light towards the photodetector 103(R) of the pixel,
of green light towards the photodetector 103(G) of the pixel,
of blue light towards the photodetector 103(B) of the pixel, and
of infrared light towards the photodetector 103(IR) of the pixel.

In other words, the entire light flux received by the portion MS1_{P} of metasurface MS1, having a surface area substantially equal to the total surface area of pixel P, is sorted by wavelength ranges. The components of the incident flux according to the considered wavelengths are deviated towards respectively photodetectors 103(R), 103(G), 103(B), and 103(IR) of the pixel. As compared with a multispectral filter based on color filters such as described in relation with FIGS. 2A and 2B, this advantageously enables to improve the quantum efficiency of the sensor since the entire flux collected in front of each pixel is transmitted towards the four photodetectors 103(R), 103(G), 103(B), and 103(IR) of the pixel.

The pattern of the portion MS1_{P} of metasurface MS1 may be repeated identically (to within manufacturing dispersions) in front of all the pixels P of the sensor. As a variant, the pattern of portion MS1_{P} may vary from one pixel P to the other, according to the position of the macropixel on the sensor, to take into account, in particular, the main direction of incidence and/or the polarization state of the rays arriving on metasurface MS1 from metasurface MS2

Those skilled in the art will be capable of adapting the embodiment of FIGS. 3A and 3B to other spectral decompositions of the measured light.

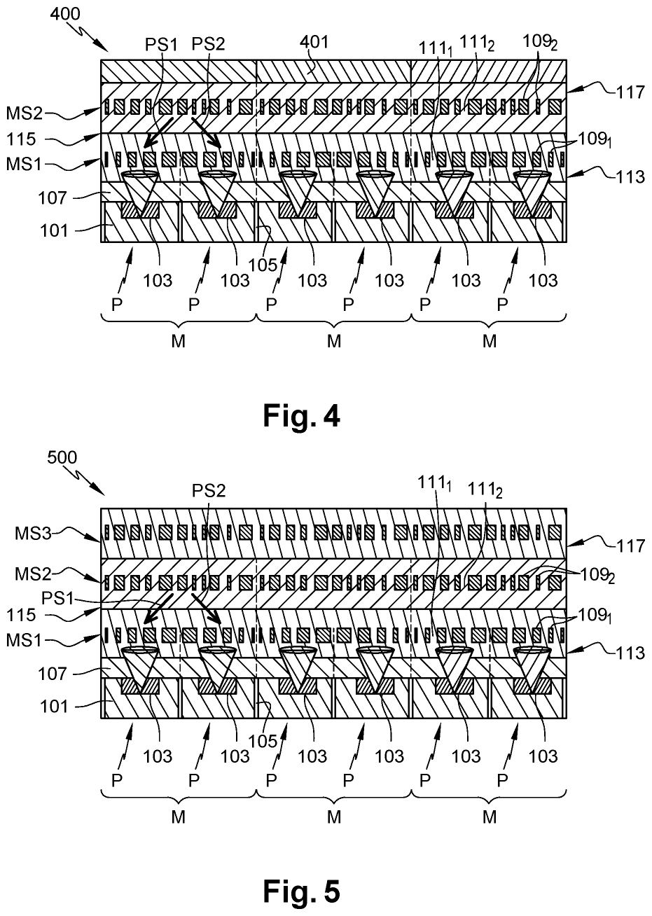

FIG. 4 is a cross-section view of an example of an image sensor 400 according to an embodiment.

The sensor 400 of FIG. 4 has the same elements as the sensor 100 of FIGS. 1A and 1B, arranged substantially in the same way.

The sensor 400 of FIG. 4 differs from the sensor 100 of FIGS. 1A and 1B in that it further comprises color filters or spectral filters 401 arranged above upper metasurface MS2, for example, on top of and in contact with transparent protection layer 117.

More particularly, in this example, each macropixel M of the sensor is topped with a filter 401 adapted to essentially letting through the light of a wavelength range to be measured. Thus, in this example, all the pixels P of a same macropixel M measure light radiations in a same wavelength range, and pixels P of neighboring macropixels M measure radiations in different wavelength ranges. For example, macropixels M are gathered in groups of 2×2 adjacent macropixels M, respectively coated with four distinct color filters 401 adapted to respectively letting through mainly red light, mainly green light, mainly blue light, and mainly infrared light.

Color filters 401 for example comprise filters made of colored resins and/or interference filters.

As a variant, the layer of color filters 401 may be arranged between upper metasurface MS2 and lower metasurface MS1, or between metasurface MS1 and substrate 101.

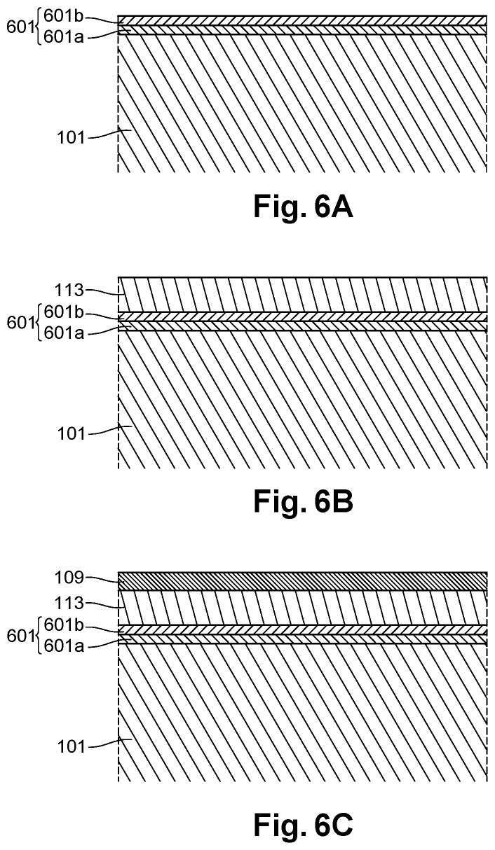

FIG. 5 is a cross-section view of an example of an image sensor 500 according to an embodiment.

The sensor 500 of FIG. 5 has elements common with the sensor 400 of FIG. 4.

These elements will not be detailed again, and only the differences with respect to sensor 400 will be highlighted hereafter.

The sensor 500 of FIG. 5 differs from the sensor 400 of FIG. 4 essentially in that, in sensor 500, color filter layer 401 is omitted and replaced with a third metasurface MS3, arranged above metasurface MS2, for example, on top of and in contact with the upper surface of transparent layer 117, adapted to implementing a function of routing of the incident light, according to its wavelength, towards respectively the different macropixels M of the sensor.

As an example, macropixels M are gathered in groups of 2×2 adjacent macropixels M. The portion of metasurface MS3 located vertically in line with each group of 2×2 macropixels, has, for example, a pattern adapted to implementing a function of routing and focusing:
of red light towards a first macropixel in the group, of green light towards a second macropixel in the group, of blue light towards a third macropixel in the group of infrared light towards a fourth macropixel in the group.

In other words, the entire light flux received by the portion of metasurface MS3, having a surface area substantially equal to the total surface area of the group of 2×2 macropixels M, is sorted by wavelength ranges. The components of the incident flux according to the considered wavelengths are deviated towards respectively the four macropixels M in the group.

As compared with a multispectral sensor based on color filters such as described in relation with FIG. 4, this advantageously enables to improve the quantum efficiency of the sensor since the entire flux collected in front of each group of 2×2 macropixels is transmitted towards the four macropixels of the group.

The pattern of the portion of metasurface MS3 covering a group of 2×2 macropixels may be identically repeated (to within manufacturing dispersions) in front of all the groups of sensor macropixels. As a variant, the pattern may vary from one group of macropixels to the other, according to the position of the macropixel on the sensor, to take into account, in particular, the main direction of incidence of the rays arriving on metasurface MS3 from the scene to be imaged.

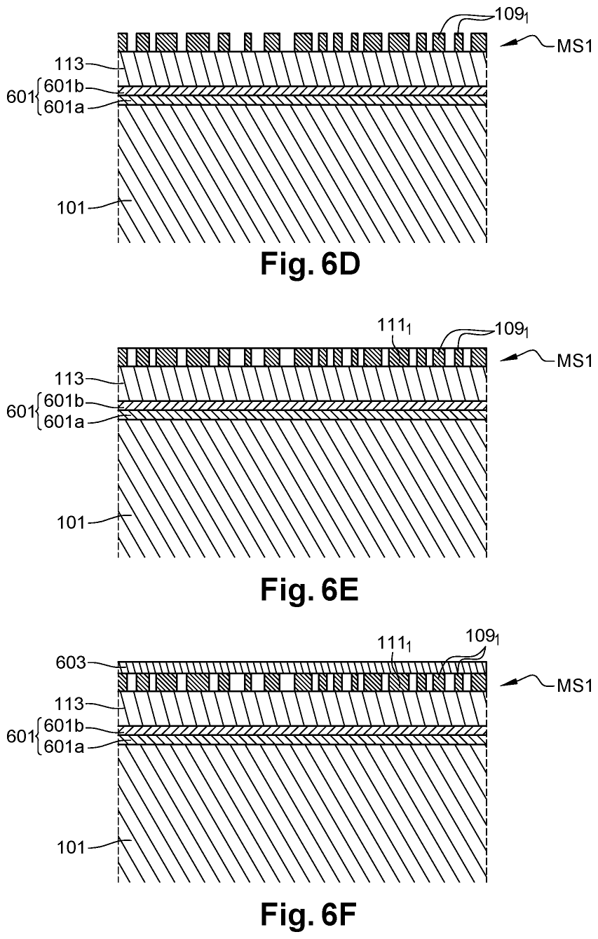

FIG. 6A, FIG. 6B, FIG. 6C, FIG. 6C, FIG. 6E, and FIG. 6F are cross-section views schematically and partially illustrating steps of an example of a method of manufacturing of an image sensor according to an embodiment, for example, a sensor of the type described in relation with FIGS. 1A and 1B.

FIG. 6A illustrates an intermediate structure comprising a semiconductor substrate 101 inside and on top of which have been formed a plurality of pixels P (not detailed in the drawing).

FIG. 6A more particularly illustrates the structure obtained at the end of a step of forming of a passivation coating 601 on the upper surface of substrate 101. Passivation coating 601 for example comprises a silicon oxide layer, a hafnium dioxide layer (HfO₂), an alumina layer (Al₂O₃), or a stack of a plurality of layers of different materials capable of fulfilling the antireflection function, extending across substantially the entire surface of the sensor. As an example, passivation coating 601 comprises a silicon oxide layer 601a formed on top of and in contact with the upper surface of interconnection stack 107, and a silicon nitride layer 601b formed on top of and in contact with the upper surface of layer 601a. Layers 601a and 601b extend for example continuously and with a substantially uniform thickness over the entire upper surface of the sensor. The thickness of layer 601a is for example in the range from 1 nm to 100 nm, for example, in the order of 10 nm. The thickness of layer 601b is for example in the range from 10 nm to 200 nm, for example, in the order of 100 nm.

FIG. 6B illustrates the structure obtained at the end of a step of forming of an optical spacer layer 113 on the upper surface of passivation coating 601, for example in contact with the upper surface of layer 601b.

The thickness of layer 113 is for example smaller than 500 μm, preferably smaller than 100 μm. As an example, the thickness of layer 113 is in the range from 1 to 50 μm, for example, in the order of 4 μm.

Layer 113 is for example made of silicon oxide.

As an example, layer 113 has a planar upper surface extending over the entire upper surface of the sensor.

FIG. 6C illustrates the structure obtained at the end of a step of deposition, on the upper surface of layer 113, for example in contact with the upper surface of layer 113, of a layer 109 made of the material intended to form the pads 109₁ of the lower metasurface MS1 of the sensor.

Layer 109 for example continuously extends with a uniform thickness over the entire upper surface of the sensor. The thickness of layer 109 is for example in the range from 50 to 500 nm, for example, in the order of 350 nm.

Layer 109 is for example made of amorphous silicon.

FIG. 6D illustrates the structure obtained at the end of a step of local etching of layer 109 across its entire thickness, for example by photolithography and etching, to define the pads 109₁ of metasurface MS1. As an example, during this step, the etching is interrupted on the upper surface of layer 113.

FIG. 6E illustrates the structure obtained at the end of a step of filling of the lateral spaces between pads 109₁ with the filling material 111₁ of metasurface MS1, for example, silicon oxide. As a variant, filling material 111₁ may have a thickness greater than that of pads 109₁ and cover the upper surface of pads 109₁.

FIG. 6F illustrates the structure obtained at the end of a step of forming of an antireflection structure 603 on the upper surface of metasurface MS1, for example in contact with the upper surface of pads 109₁ and of the filling material. Structure 603 may be formed by a stack of one or a plurality of dielectric layers. The thickness of antireflection structure 603 is for example in the range from 100 to 500 nm, for example in the order of 200 nm.

The steps of FIGS. 6GB, 6C, 6D, 6E, and 6F may be repeated once or a plurality of times to form one or a plurality of additional metasurfaces above metasurface 603.

A step of local etching of the stack formed above substrate 101 may further be provided to form one or a plurality of contacting vias.

Various embodiments and variants have been described. Those skilled in the art will understand that certain features of these various embodiments and variants may be combined, and other variants will occur to those skilled in the art. In particular, the described embodiments are not limited to the examples of dimensions and of materials mentioned in the present disclosure for the forming of the metasurfaces.

Further, the described embodiments are not limited to the examples of optical functions mentioned hereabove implemented by the metasurfaces.

Further, the described embodiments are not limited to the above-described examples of application to visible or near infrared sensors. Other wavelength ranges may take advantage of an integration, at the pixel scale, of metasurfaces stacked on the side of the sensor illumination surface. For example, the described embodiments may be adapted to infrared sensors intended to measure radiations of wavelength in the range from 1 to 2 μm, for example, based on InGaAs or on germanium.

Image sensor (100; 200; 300; 400; 500) formed inside and on top of a semiconductor substrate (101), the sensor may be summarized as including a plurality of pixels (P), each comprising a photodetector (103) formed in the substrate, the sensor comprising at least first (MS1) and second (MS2) bidimensional metasurfaces stacked, in this order, in front of said plurality of pixels, each metasurface being formed of a bidimensional array of pads (109₁, 109₂), the first metasurface having a first optical function and the second metasurface having a second optical function different from the first optical function.

The first (MS1) and second (MS2) metasurfaces may be at a distance from the semiconductor substrate (101) shorter than 500 μm, for example shorter than 100 inn.

The first metasurface (MS1) may be at a distance from the semiconductor substrate (101) in the range from 1 to 50 inn, and the second metasurface (MS2) may be at a distance from the first metasurface (MS1) in the range from 1 to 50 inn.

The pads (109₁) of the first metasurface (MS1) and the pads (109₂) of the second metasurface may be made of amorphous silicon.

The pads (109₁) of the first metasurface (MS1) and the pads (109₂) of the second metasurface may be laterally surrounded with silicon oxide.

The pads (109₁, 109₂) of the first (MS1) and second (MS2) metasurfaces may have sub-wavelength lateral dimensions.

The first optical function may be a function of routing of the incident light according to its polarization state, and the second optical function may be a function of focusing of light towards the photodetectors (103) of the underlying pixels (P).

Image sensor (200) may include a layer of color filters (201) between the first metasurface (MS1) and the substrate (101).

Image sensor (400) may include a layer of color filters (401) above the second metasurface (MS2).

Image sensor (500) may include, above the second metasurface (MS2), a third metasurface (MS3) adapted to implementing an optical function of routing of the incident light according to its wavelength.

The first optical function may be a function of routing of the incident light according to its polarization state, and the second optical function may be a function of routing and focusing of light towards the photodetectors (103) of the underlying pixels (P), according to its wavelength.

In top view, the pads (109₁) of the first metasurface (MS1) and/or the pads (109₂) of the second metasurface (MS2) may have asymmetrical shapes, for example, rectangular or elliptic.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
an image sensor inside and on top of a semiconductor substrate, the sensor comprising:
a plurality of pixels, each comprising a photodetector formed in the substrate;
at least first and second bidimensional metasurfaces stacked, in this order, in front of the plurality of pixels, each metasurface being a bidimensional array of pads, the first metasurface having a first optical function and the second metasurface having a second optical function different from the first optical function.

2. The device according to claim 1, wherein the first and second metasurfaces are at a distance from the semiconductor substrate shorter than 500 μm, for example shorter than 100 μm.

3. The device according to claim 1, wherein the first metasurface is at a distance from the semiconductor substrate in the range from 1 to 50 μm, and the second metasurface is at a distance from the first metasurface in the range from 1 to 50 μm.

4. The device according to claim 1, wherein the pads of the first metasurface and the pads of the second metasurface are of amorphous silicon.

5. The device according to claim 1, wherein the pads of the first metasurface and the pads of the second metasurface are laterally surrounded with silicon oxide.

6. The device according to claim 1, wherein the pads of the first and second metasurfaces have sub-wavelength lateral dimensions.

7. The device according to claim 1, wherein the first optical function is a function of routing of the incident light according to its polarization state, and the second optical function is a function of focusing of light towards the photodetectors of the underlying pixels.

8. The device according to claim 7, comprising a layer of color filters between the first metasurface and the substrate.

9. The device according to claim 7, comprising a layer of color filters above the second metasurface.

10. The device according to claim 7, comprising, above the second metasurface, a third metasurface adapted to implementing an optical function of routing of the incident light according to its wavelength.

11. The device according to any claim 1, wherein the first optical function is a function of routing of the incident light according to its polarization state, and the second optical function is a function of routing and focusing of light towards the photodetectors of the underlying pixels, according to its wavelength.

12. The device according to claim 1, wherein, in top view, the pads of the first metasurface and/or the pads of the second metasurface have asymmetrical shapes, for example, rectangular or elliptic.

13. A device, comprising:
a substrate;
a plurality of pixels on the substrate;
a first metasurface on the plurality of pixels, the first metasurface having a plurality of cells that align with the plurality of pixels; and
a second metasurface on the first metasurface, the second metasurface having a plurality of portions, each portion aligning with a group of the plurality of cells.

14. The device of claim 13, wherein the first metasurface includes a transparent material that includes a plurality of pads.

15. The device of claim 14, wherein the plurality of pads are amorphous silicon.

16. The device of claim 14, wherein the plurality of pads are silicon nitride.

17. A device, comprising:
a substrate;
a first pixel on the substrate;
a second pixel on the substrate;
a first metasurface on the first and second pixels, the first metasurface including a first portion on the first pixel and a second portion on the second pixel;
a second metasurface on the first metasurface, the second metasurface including a transparent material round a pattern of pads.

18. The device of claim 17, wherein the plurality of pads are opaque to radiation measured by the first pixel and the second pixel.

19. The device of claim 18, wherein the plurality of pads are amorphous silicon.

20. The device of claim 18, wherein the plurality of pads are silicon nitride.
